(19) United States
(12) Patent Application Publication
(10) Pub. No.: US 2011/0185971 A1
(43) Pub. Date: Aug. 4, 2011

(54) Laser doping

(75) Inventors: David J. Elliott, Carlisle, MA (US); Kenneth J. Harte, Carlisle, MA (US); Ronald P. Millman, JR., Taunton, MA (US); Victoria M. Chaplick, Charlton, MA (US); Eugene O. Degenkolb, Newton, MA (US)

(73) Assignee: UVTech Systems, Inc., Sudbury, MA (US)

(21) Appl. No.: 12/956,302

(22) Filed: Nov. 30, 2010

Related U.S. Application Data
(60) Provisional application No. 61/283,194, filed on Nov. 30, 2009.

(51) Int. Cl. H01L 21/00; C23C 16/458; C23C 16/52

(52) U.S. Cl. 118/712

(57) ABSTRACT

The disclosed apparatus and method provides substrate impurity doping wherein a laser rapidly scans a substrate while simultaneously a uniform laminar flow of reactive gas is injected, the interaction of the laser radiation and the dopant results in a uniform diffusion of the dopant species in all planes (X,Y,Z) of the substrate. Laser energy density, wavelength, and pulse geometry are adjustable, in a simple system for volume manufacturing, to provide depth and dose control of the dopant. The system optics can be focused to form a high resolution laser beam to directly write the doping area pattern geometry. Alternatively the laser beam can be optically expanded to form a large diameter beam for large area diffusion of the dopant through a patterned mask.

### RELATED APPLICATION(S)

This application claims the benefit of U.S. Provisional Application No. 61/283,194, filed on Nov. 30, 2009. The entire teachings of the above application(s) are incorporated herein by reference.

### BACKGROUND OF THE INVENTION

The present patent application discloses an apparatus and method for imparting a dopant into the surface of a substrate, including for example, a semiconductor substrate. Specifically the present disclosure relates to direct laser doping where a high degree of control of the dopant dose and profile is needed. The present disclosure further relates to laser doping of a substrate in which the amount of dopant deposited is precisely controlled and where the depth of penetration and resulting 3-dimensional profile of the dopant in the substrate must be precisely controlled. The present disclosure further relates to an apparatus of using a laser and a dopant and a substrate in a process chamber, wherein the laser beam is transmitted through the window of the chamber, and the dopant is interacted with the laser beam and the substrate so as to cause the diffusion of the dopant species into the surface of the substrate.

Dopants are widely used in the fabrication of integrated circuits, solar cells, flat panel displays, thin film heads and other opto-electronic solid state devices. Dopants act as impurities to alter the electrical properties by forming conductive pathways inside the structure of a semiconductor film layer. Dopant species include boron, phosphorus, or arsenic. Precise amounts of these dopant impurity materials are energetically incorporated into the surface of the substrate being doped, for example, a semiconductor such as silicon wafer. Semiconductor doping methods fall broadly into three methods: Ion Implantation, Plasma Doping and Laser Doping.

Ion Implantation has for many years provided a cost effective method for volume manufacturing of semiconductor devices. The Ion Implantation method involves providing a dopant material into a chamber where a plasma is created. Selected ions from the generated plasma are then accelerated to energy levels up to several hundred kilovolts. The accelerated ions are directed to the semiconductor surface and physically driven into the substrate. The Ion Implantation process gives uniform coverage of a surface with precise and reproducible dopant dose control and accurate dopant profiles.

Another method for placing impurity ions into a surface film is plasma doping. The plasma doping method involves generating a plasma in which a specific dopant concentration is provided in a gas, and the substrate, such as a semiconductor wafer, is exposed to the ions coming out of the plasma. The plasma doping reactor resembles that used for Reactive Ion Etching, where the wafer rests on the RF-powered cathode, and the gas discharge is either on continuously or pulsed by the power supply. The gas discharge causes reaction of dopant molecules with all chemical species on the reactor surfaces, including water vapor, producing a mixed population of chemicals in the plasma. Unlike Ion Implantation, there is no mass separation, so the wafer receives a variety of dopant ions coming from the plasma.

Ultra High Dose (UHD) Implants can be made with plasma doping, making a conformal coating rich in dopant species. This low energy process is useful to make high performance, 3D transistors. High dopant concentrations and low energy methods are useful also to form ultra shallow junctions as required in advanced integrated circuit devices. Some of these methods are called ‘Cluster Ion Doping’. Ion Implantation is not practical at such low energy levels.

Laser Doping is another method also used to alter the electrical properties of a semiconductor material. Generally the substrate is placed in a chamber in the presence of dopant gasses, while simultaneously laser radiation is directed to the substrate. Laser doping works by having the intense laser energy liquefy the substrate surface approaching the melting point thereby allowing the dopant to penetrate and become activated. Laser doping can produce a wide range of dopant concentrations with good uniformity and depth control. Variations of laser doping are being evaluated to increase efficiency, such as, for example, providing additional energy drivers including magnetic heating or direct heating.

Semiconductor technology has traditionally been driven by ‘Moore's Law’, a formula written by Intel founder Gordon Moore predicting a doubling of the number of devices in a given area every two years. This ‘law’ has been operable over several decades of device generations, with much smaller and faster integrated circuits, memory chips and microprocessors, making possible widespread proliferation of useful computing and communicating devices at continually lower costs.

Recently, however, the possible limits of conventional processes and methods used to fabricate solid state devices, such as Ion Implantation, are being reached in the most advanced designs, especially at the 32 nm and 22 nm node levels. For example, the tolerable levels of damage to the silicon crystal that occurs during Ion Implantation (requiring the anneal step) inevitably causes small electrical leaks in the finished device. Such leaks contribute to power consumption. At the 32 nm node level, leakage on low power transistors is negatively impacting yields. In order to compensate for this problem, integrated circuit manufacturers are making typically three individual ion implant process steps instead of one, referred to as ‘source-drain engineering’ in the language of IC process engineers. In doing so, they use the 2^{nd} and 3^{rd} doping ‘runs’ to adjust the electrical parameters of the device precisely. This reduces throughput and adds considerable cost to the process.

Also, the small feature sizes at the 32 nm and 22 nm node levels are much more angle sensitive to the batch ion implant process, causing inaccurate placement of dopant profiles, a problem especially critical on ultra-shallow junctions. This so-called ‘Cone Angle Effect’ that causes shadowing of the ions by resist topography at these 32 nm and 22 nm nodes can be reduced by eliminating batch ion implantation, in favor of single wafer ion implantation. However, this reduces wafer throughput significantly and therefore increases cost. The future growth of semiconductor technology rests largely on cost reduction, so processes that significantly increase costs are likely to be supplanted by methods that permit lower cost per function.

In short, effective device scaling at the 32 nm and 22 nm nodes and below poses serious technological challenges to current ion implant processes, the standard doping method for the majority of semiconductor devices made worldwide. These technology challenges may prevent the current methods from being used on future device designs. New methods of doping are therefore being explored permit further device scaling for higher performance, lower cost devices for use in all semiconductor-based devices.

The high device speeds and extreme geometry resolution at 32 nm and below require shorter gate lengths and higher control of threshold voltage. Precise control of threshold voltage requires precise control of dopant dose. And shorter gate lengths, where current leaks occur at the deep portion of the doped region, require that doping be performed only in the shallow areas of the surface region. In other words, processes for shallow junction formation are necessary.

Ion implantation, then, is limited in its ability to meet the requirements of 32 nm technology, and below. The crystal damage caused by ion implant requires an added annealing step, the heat from which may cause undesirable diffusion of the dopant. The cone angle or incident angularity is another limit to conventional ion implantation process. Finally, ion implanters are extremely large, complex machines taking up valuable clean room space and requiring several highly trained specialists to operate in a manufacturing environment.

Plasma doping, with no mass separation, is more efficient but suffers from the limitation of precise dopant concentration control. The changing ratios of dopant gas, diluting gas and impurities such as water vapor are difficult to precisely manage, creating limits to this method. Plasma doping is also subject to limitations in RF field uniformity across the reactor.

Laser doping has also been limited by the ability to control precisely the amount of dopant ions reaching the wafer. Uniform distribution of the impurity ions has been a limiting factor. Part of this problem is caused by non-uniform laser radiation, and other parts of the problem can be caused by non-uniform gas flow and dopant density variation in that flow. The apparatus practiced in the prior art used large gas excimer lasers that are not suitable for production manufacturing due to high maintenance and high cost of ownership, and also unreliable and non-repeatable optical performance. Large variations in the pulse shape and intensity of prior art lasers used for laser doping have prevented this technology from being used in production.

Accordingly, the art needs a doping apparatus that provides increased production throughput, lower downtime for maintenance, lower cost of ownership and greater flexibility of configuration and control to permit multiple doping recipes in a simple, easy-to-use system, low operating cost system.

Particularly the art needs a doping system that eliminates the substrate damage caused by conventional ion implantation and therefore eliminates the need for subsequent processing steps to anneal or remove the damage to, for example, the silicon crystal structure of the silicon wafers used to make integrated circuits. The art also needs a doping method that overcomes the limitations of current ion implantation caused by non-uniform energy deposition, and more specifically the problem of high temperatures induced into the substrate during the doping process. Also needed is a doping method that eliminates the formation of the dense, carbon crust formed during ion implantation when high intensity ions compress and ‘carbonize’ the top layer of the photoresist mask used to pattern the dopant ions into the silicon substrate.

### SUMMARY OF THE INVENTION

In view of the limitations of the previously stated prior art methods, it becomes desirable to do one or more of the following: (1) provide an apparatus for laser doping, where the apparatus is very simple and easy to use, (2) wherein a high degree of dopant uniformity is provided, (3) where precise control of dopant concentration in the depth of the substrate is provided, (4) where the thermal and physical substrate damage problems are minimized, (5) where the operating cost is significantly reduced compared to the prior art, and (6) where the reliability and reproducibility of the apparatus is suitable for high volume manufacturing. (7) Finally, it is desirable to provide an apparatus and method for laser doping that is both environmentally friendly and energy efficient in light of the prior art.

(1) The present disclosure provides an apparatus for laser doping that has a very simple design with few moving parts, and can be easily run by a properly trained technician.

(2) The laser doping system of the present disclosure is capable of landing a highly uniform dose of intense photon radiation to permit uniform doping profiles. This is made possible by programmed and precisely controlled scans of the beam over the substrate surface. A wide variety of scan algorithms are loaded into the system as ‘recipes’ to meet different doping requirements. In addition, within each scan, uniformity is further enhanced by the optical shaping of each individual laser pulse.

(3) The present disclosure also provides a method and apparatus of direct laser doping with a high degree of depth control made possible by optically flattening the beam profile in this ‘Z’ or depth plane and by the proper and simple selection of laser wavelengths within the apparatus. Each wavelength will provide a characteristic absorption profile in the dopant material and substrate, and so multiple wavelengths are made available and easily changed by discrete modules on the apparatus of the present disclosure.

(4) In addition, the present disclosure provides a laser doping apparatus and method and that reduces or eliminates the problems of high temperature melting and surface damage to the substrate. In the prior art, these problems require additional process steps to repair the substrate before subsequent processing. The combination of the selection of laser energy density, laser wavelength, and laser scan method of the apparatus of the present disclosure make it possible to perform laser doping to semiconductor substrates without melting or significantly damaging the substrate, thereby eliminating the need for added steps to repair crystal damage. Laser wavelengths with low photon energy are used with an optimized reprate (pulses per second) and fluence (mJ/cm²) to provide high peak power in extremely short timeframes. Since the ions are not physically driven in as in ion implantation, the thermal annealing step is eliminated, as is crystal damage.

(5, 6) Also, in the present disclosure, cost is reduced by using a simple apparatus including a small solid state laser source and high speed scan head, subsystems with high reliability, few moving parts and low maintenance requirements.

(7) The apparatus of the present disclosure for laser doping requires very little electrical energy since high energy photons from a small solid state laser is the principal energy driver for doping. Further, the substrate does not require being heated, and since the laser doping process does not create a carbonized crust on the surface of the doping mask, hazardous and toxic chemicals normally used to remove the carbonized mask are not required. In terms of both energy usage and chemistry used, the apparatus of the present disclosure is efficient and environmentally friendly.

The present disclosure therefore has the effect that laser radiation is highly uniform, controllable and adjustable to permit shallow junction formation, to permit a low thermal budget and not melt the silicon, and eliminate substrate damage and the added annealing step of the prior art. The present disclosure has the effect of permitting a cost effective and simple method and apparatus of doping a substrate that is needed in the critical technology area of integrated circuit manufacturing. The present disclosure further anticipates the need for cost reduction while reducing the impact on the environment.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 (on the left hand side (A)), is a schematic top and side view of a prior art Gaussian laser beam, along with an actual photo of the Gaussian beam illustrating the beam non-uniformity.

FIG. 1 (on the right hand side (B)), is a schematic top and side view of the beam of the present disclosure, a square-top-hat beam, along with an actual photo of the beam illustrating the beam uniformity.

FIG. 2 is a graph of the horizontal and vertical cross-section of the laser beam of the present disclosure, and a 3-dimensional pictorial graph of the same beam. All three graphs illustrate the size, uniformity, and fluence (energy per unit area) of a single laser pulse.

FIG. 3 is a pictorial graph of several laser pulses of the present disclosure placed together to illustrate how individual pulses can be laid down like tiles to make a uniform dose of energy.

FIG. 4 is a thermogram of laser pulses of the present disclosure, scanned over a 200 mm silicon wafer, to illustrate uniformity of exposure over a large area.

FIG. 5 is a pictorial graph from a beam analyzer of sequential scans of the laser beam across a surface. The pulses are offset to increase the uniformity of the dose.

FIG. 6 is a time sequence of non-adjacent placement of laser light pulses to minimize local heating and surface damage effects.

FIG. 7A is an isometric view of a laser doping apparatus in accordance with the present disclosure.

FIG. 7B is a cutaway front view of the primary sub-systems of a laser doping apparatus in accordance with the present disclosure.

FIG. 7C is a cutaway side view of the primary sub-systems of a laser doping apparatus in accordance with the present disclosure.

FIG. 7D is a cutaway top view of the wafer loading robotic sub-system and chamber portions of a laser doping apparatus in accordance with the present disclosure, showing how wafers are loaded and unloaded.

FIG. 7E is a cutaway top view of the optical baseplate showing placement of the laser, scan head, mirrors and optics of a laser doping apparatus in accordance with the present disclosure.

FIG. 7F is a schematic top view of the placement of two different lasers on the system baseplate of a laser doping apparatus in accordance with the present disclosure, showing special modules for 266 nm and 355 nm wavelength laser exposures.

FIG. 8 is a cross-sectional process flow diagram of an ion doping method in accordance with the prior art illustrating a semiconductor device in which impurity ions are implanted into a silicon wafer using a resist mask.

FIG. 9 is a cross sectional process flow diagram of a laser doping method in accordance with the present disclosure illustrating a semiconductor device in which impurity ions are implanted into a silicon wafer using a resist mask.

FIG. 10 is a cross sectional process flow diagram of a mask-less direct laser doping method in accordance with the present disclosure.

FIG. 11 is a graph of electrical data of laser doping of boron on a boron-doped substrate in accordance with the present disclosure.

FIG. 12 is a graph of electrical data of laser doping of a junction of boron on a phosphorus-doped film formed in accordance with the present disclosure.

FIG. 13 is a graph of electrical data of laser doping of a junction of phosphorus on a boron-doped substrate formed in accordance with the present disclosure.

FIG. 14 is an atomic force micrograph of the surface of a wafer following laser doping in accordance with the present disclosure.

FIG. 15 is a graph of dopant concentration as a function of laser energy per unit area (fluence) in accordance with the present disclosure.

FIG. 16 is a table listing the results of various test configurations.

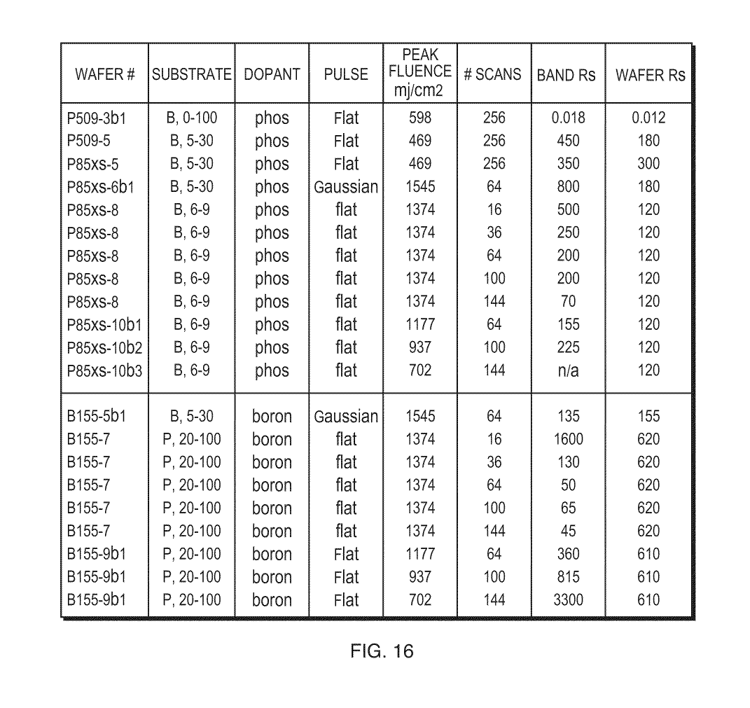

FIG. 17 is a table showing eight other test cases.

### DETAILED DESCRIPTION OF THE INVENTION

A description of example embodiments of the invention follows. Hereinafter, the present disclosure will be described by way of one or more illustrative examples with reference to the accompanying drawings as appropriate. In no way is the description of a particular embodiment, or the objects stated above, intended to limit the scope of any invention claimed.

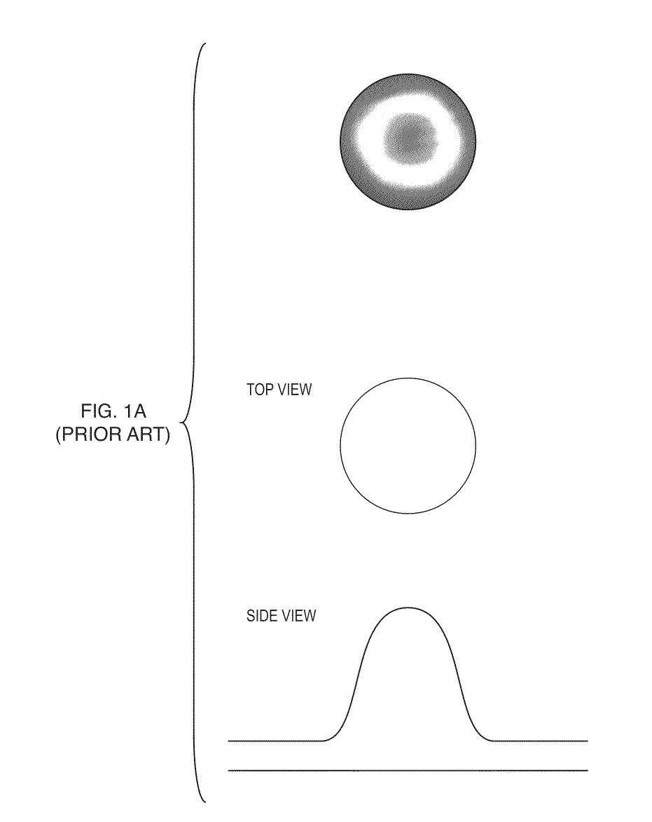

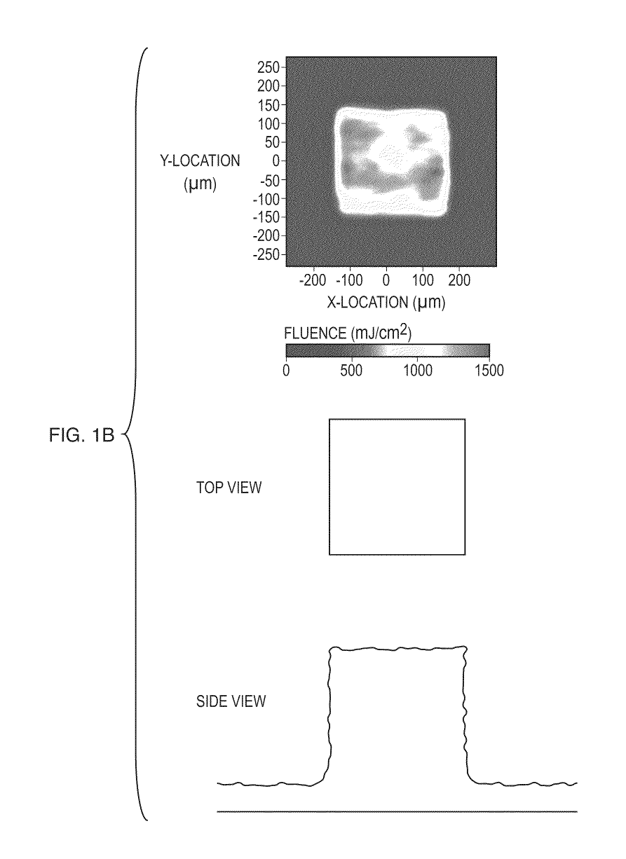

FIG. 1(A) is a schematic top and side view of the Gaussian laser beam intensity profiles according to the prior art. FIG. 1(A) shows also top and side views of the prior art laser beams, indicating a concentrated area of high intensity in the center of the beam. This central hot spot makes it difficult to process materials uniformly since the peak intensity in the middle of the beam is many times the intensity at the edges of the beam. Further, laser beams of this typical shape cannot be easily overlapped without causing additional hot spots or areas of non-uniform radiation.

FIG. 1(B) is a schematic top and side view of a square, flat-top laser beam, a preferred embodiment of the present disclosure. The beam intensity profiles of the flattop beam show that squares of uniform light can be put together like tiles to make a uniform blanket of laser radiation.

This is necessary in semiconductor processing, where extremely thin films of oxides, silicides, metals, and organometallics are widely used to make integrated circuits. Non-uniform radiation will cause damage to these thin, delicate films, rendering the integrated circuit useless. Loss of device yield in an integrated circuit manufacturing line is the most serious problem.

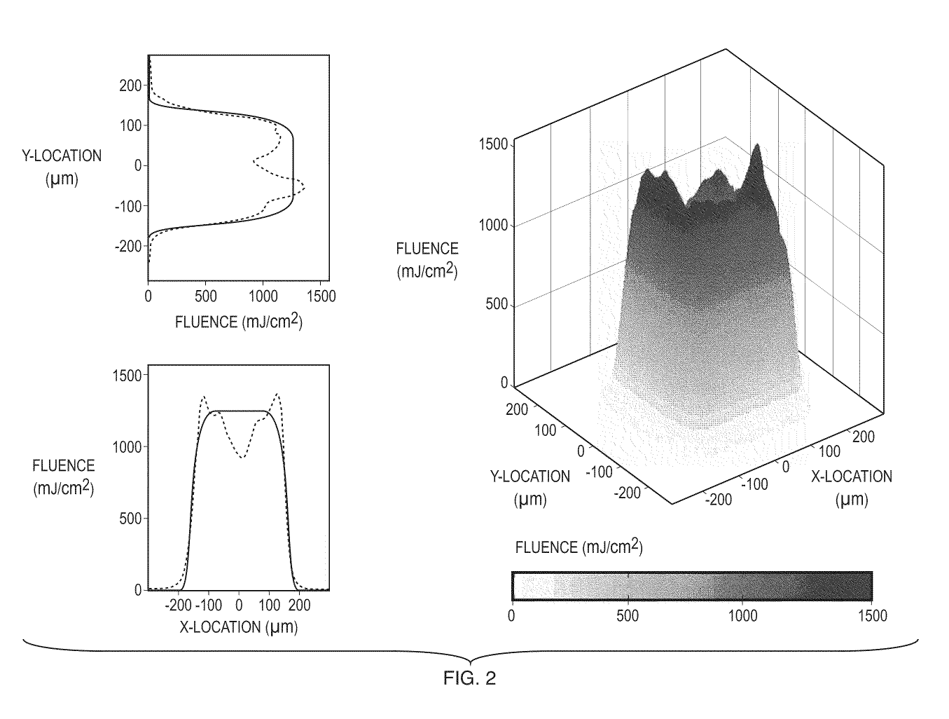

FIG. 2 is a graph of the horizontal and vertical cross section of the laser beam of the present disclosure, and a 3-dimensional pictorial graph of the same beam. All three graphs illustrate the size, uniformity, and fluence (energy per unit area) of a single laser pulse. Note that the central ‘hot’ spot that is typical of the prior art laser beam is removed, permitting a significantly more uniform pulse of energy to be deposited onto semiconductor wafers for surface reactions such as laser doping, cleaning, and etching.

FIG. 2 also shows how the fluence delivered to the sample surface varies as a function of position within a typical rectangular flat-top laser pulse. The data contained in the 3-dimensional figure defines the key uniformity parameter to be minimized, namely:

Fluence non uniformity=Fluence(maximum−minimum)/Fluence mean.

Minimizing this fluence nonuniformity is a critical requirement in order for this apparatus to achieve its greatest process latitude or “headroom” for effective doping with minimum damage to the substrate. The figure also includes 2-dimensional cross-sections of the center of the laser pulse in the x and y directions (parallel to the rectangular pulse edges.)

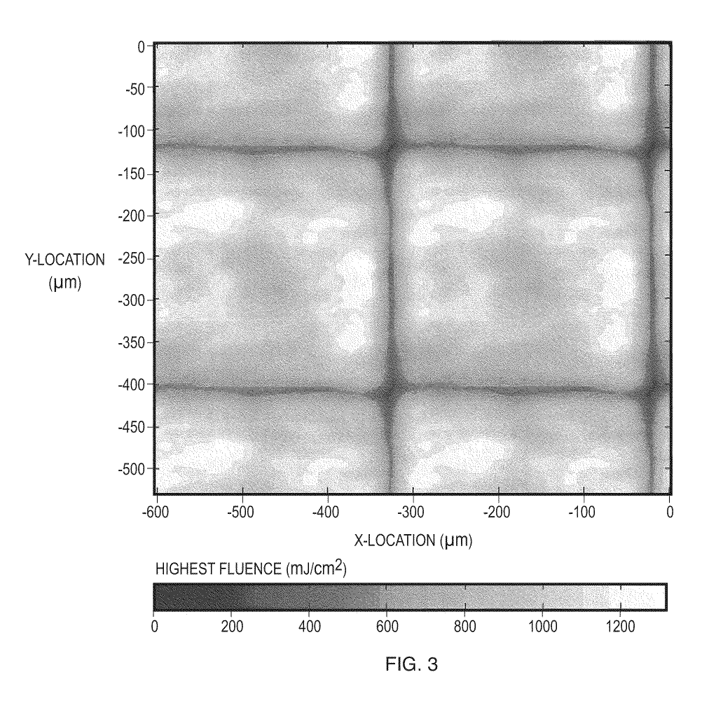

FIG. 3 is a pictorial graph of several laser pulses of the present disclosure, placed together to illustrate how individual pulses can be laid down like tiles to make a uniform dose of energy. Note that unlike the prior art which typically uses the natural round pulse shape as it comes from the laser source, the present disclosure uses a diffracting element to re-shape the laser pulse into a square. This eliminates the non-uniformity that occurs when attempting to cover an area with round pulses. The gaps must be filled in, resulting in non-uniform dose and locally higher fluence, which in turn causes damage to the thin delicate films used in integrated circuit manufacturing. In laser doping, the overlapped areas of high intensity of the prior art would cause non-uniform doping, and the dopant would be driven deeper into the silicon in the overlapped areas of the prior art beam. The square beam of the present disclosure eliminates this problem.

FIG. 3 further illustrates the placement of adjacent rectangular pulses to fill a surface area, such as a 300 mm or 450 mm silicon wafer, with a single scan of the laser. The x-spacing and y-spacing between adjacent pulses is programmable, so that the integrated fluence or dose uniformity may be minimized.

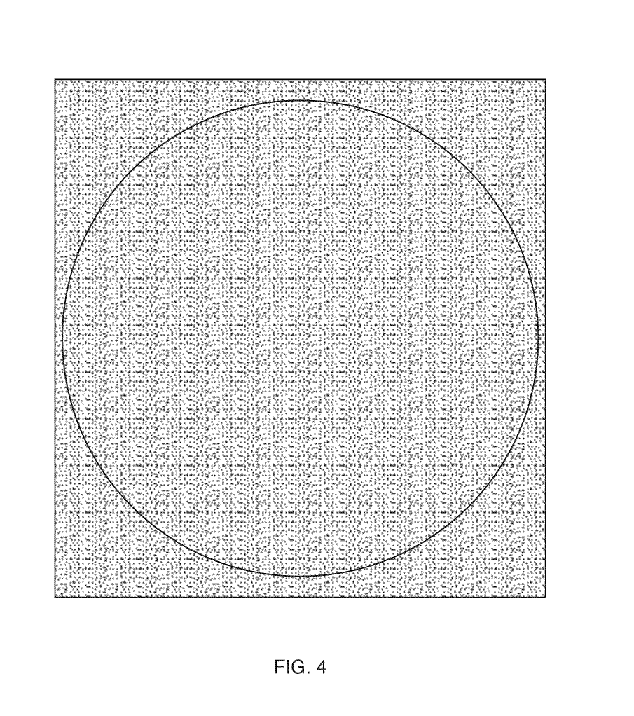

FIG. 4 is a thermogram of laser pulses of the present disclosure, scanned over a 200 mm silicon wafer to illustrate uniformity of exposure over a large area. Since individual pulses are placed next to each other according to a software program, the size of the area that can be exposed is not limited by an image forming lens system as in the prior art. For example, the pulses can be directed by the scan head to uniformly cover a 450 mm silicon wafer with approximately the same uniformity as is achieved in FIG. 4 on a 200 mm wafer. There is only an f-theta scan lens between the scan mirrors that direct the laser beam and the wafer. In the prior art doping systems, uniformity problems occur since the energy comes from a single source point, and as the area of the wafer increases, the energy at the edges is considerably less than in the center. In integrated circuit manufacturing, significant economies are realized by using increasingly larger silicon wafers.

Originally wafers were ˜1 inch in diameter, in the 1960's timeframe when integrated circuit production began. In the 1970's timeframe, wafer diameters increased to 3-4 inches diameter, and further to 5-6 inches diameter in the 1980's. In the last decade, wafers were predominately 200 mm diameter, but the introduction of 300 mm wafers began. Currently, 450 mm wafers are being prototyped. The present disclosure permits the uniform exposure of 450 mm wafers since the beam is square in shape, and can be scanned over large areas without sacrificing the necessary dose uniformity.

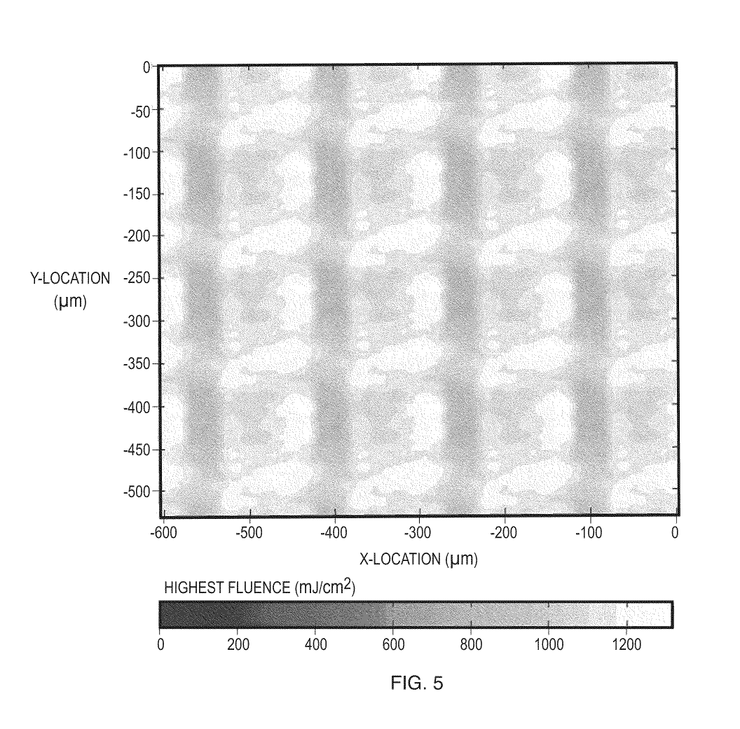

FIG. 5 is a pictorial graph from a beam analyzer of sequential scans of the laser beam across a surface. The pulses are offset to increase dose uniformity. According to the present disclosure, the number of scans used to create a single dose can be varied from one to 512. Typically either four or sixteen scans are used, as sufficient uniformity is achieved with as few as four scans. The advantage of using fewer scans is increased wafer throughput. For example, a 200 mm wafer can be laser doped in less than a minute with four scans, using a small 12 watt solid state laser. This is highly cost effective, since prior art laser doping systems employ expensive and complex ion sources, with large ion optical columns to deliver the energy to the wafer. The present disclosure, using four or sixteen scans, will not cause any significant temperature rise at the wafer surface. The highest temperature measured with the apparatus of the present disclosure is ˜100 degrees centigrade, compared to temperatures in the range of 200-400 centigrade in prior art ion implantation systems. High temperatures created during laser doping of the prior art systems causes the wafer to warp, and also may change the junction depths of prior implanted dopants.

The present disclosure, using a wavelength in the range of 250-550 nm, does not deposit significant thermal energy since these wavelengths are rapidly absorbed and scattered at the surface of the wafer, and never penetrate into the bulk of the silicon wafer. This is a further advantage, as the work of doping must occur at the surface, and doping of shallow junctions, for example, needs to be less than 500 angstroms into the wafer.

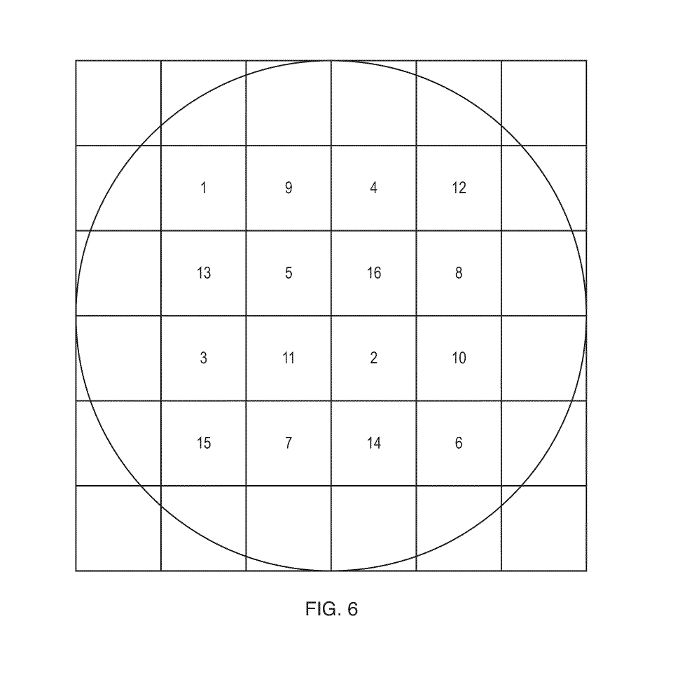

FIG. 6 is a time sequence of non-adjacent placement of laser light pulses to minimize local heating and the resulting surface damage effects caused when pulses are deposited next to each other. By spacing pulses two or more beam diameters when firing a pulsed laser, the heat from each pulse has a chance to dissipate as an isolated event, with no other pulses immediately landing next to it. Later on in the laser exposure program, a pulse finally is landed next to the spot where a pulse was previously landed, but no heat can build up from the two pulses, as each pulse's heat effect is isolated in both time and space.

We call this a ‘non-adjacent placement algorithm’, a method of spreading out laser pulses so the wafer surface never sees two pulses adjacent in space and time. When pulses are fired in a row, adjacent to each other, significant heat can arise, causing the underlying surface to roughen or even ablate. Ablation basically removes a portion of the surface, violently as in a micro-explosion. Photoablation is a well documented phenomenon. A preferred embodiment of the present disclosure is to deposit laser pulses on a surface in a manner that avoids pulse adjacency.

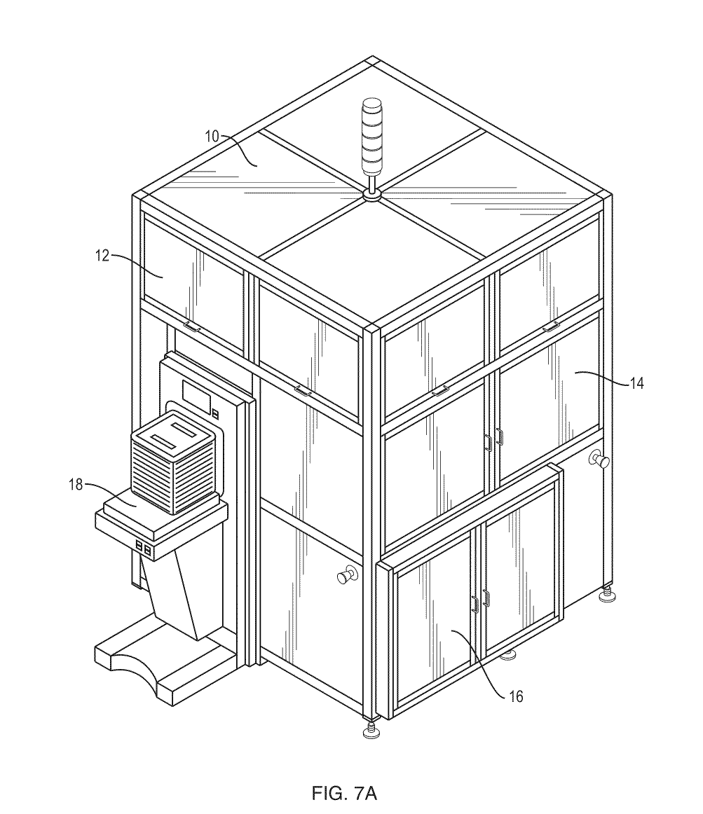

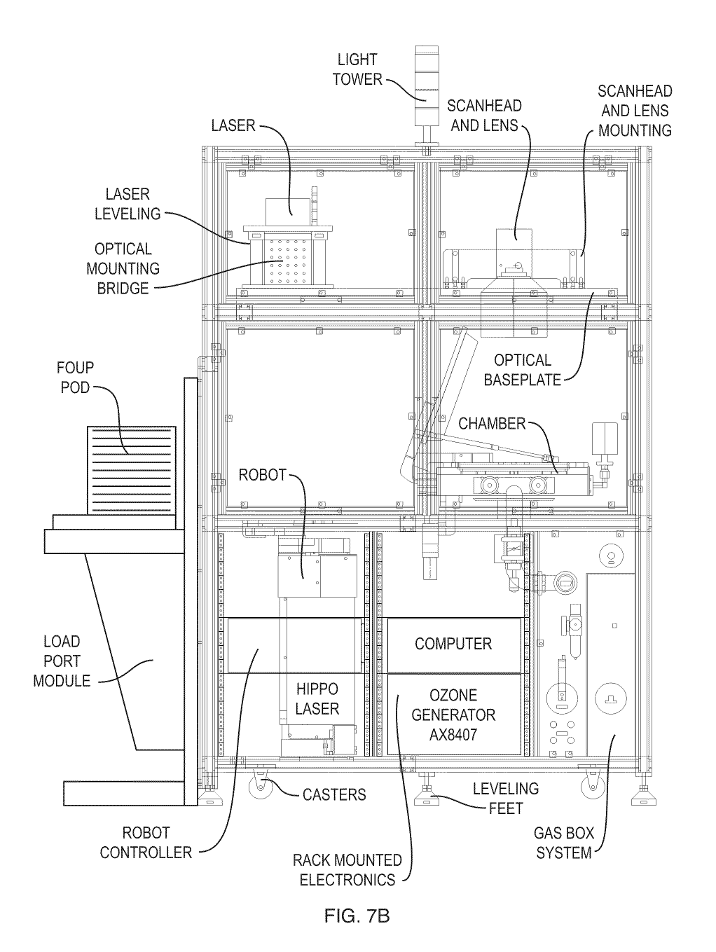

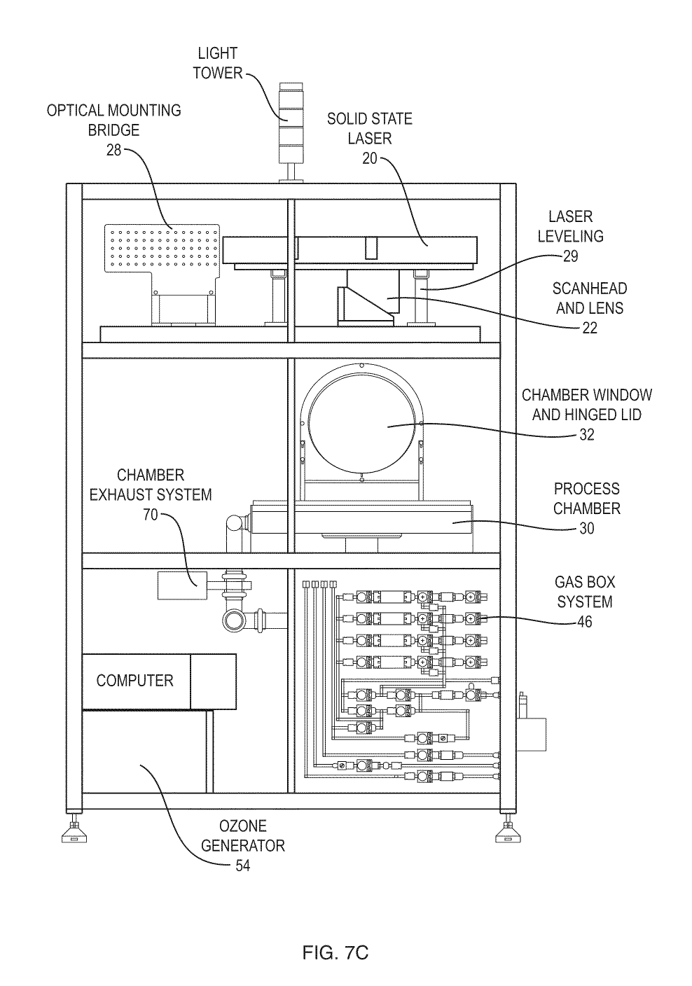

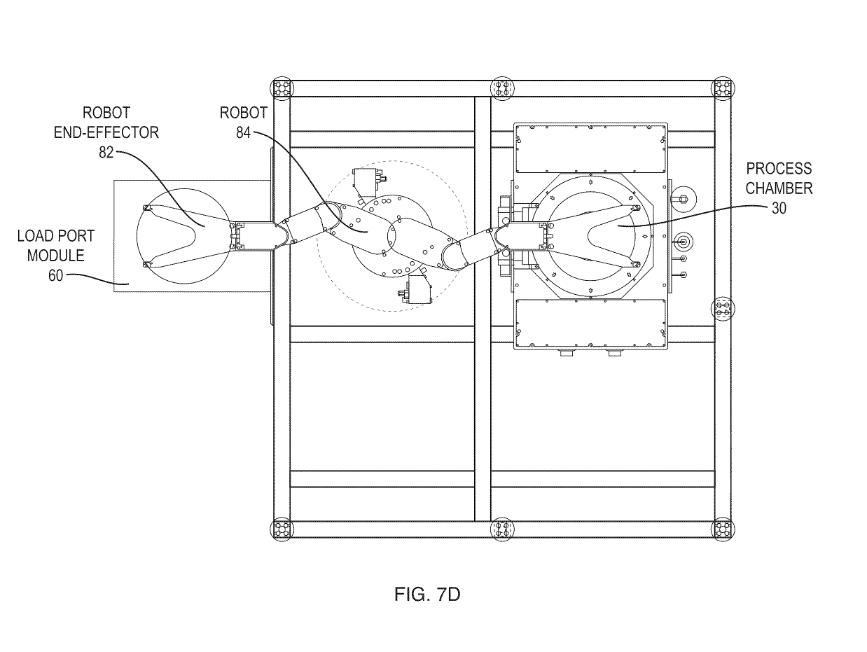

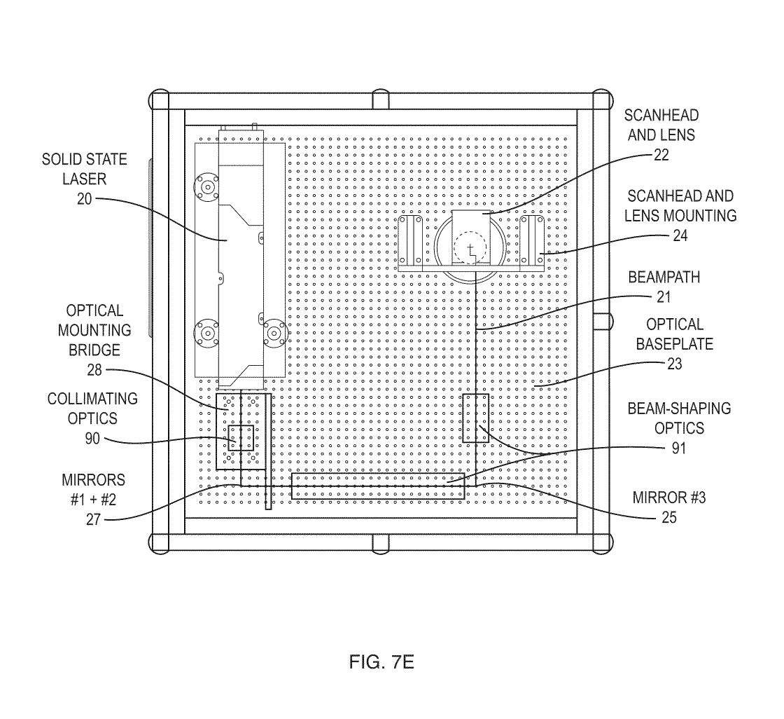

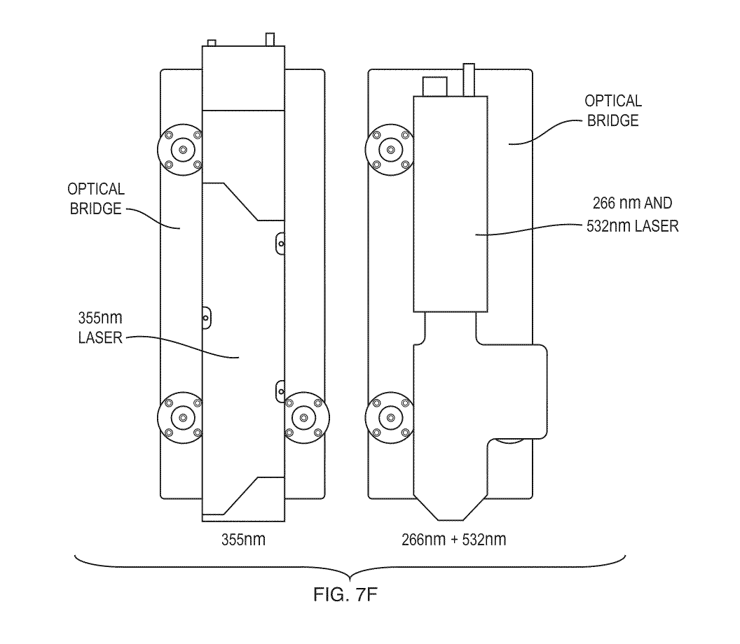

FIG. 7A illustrates embodiments, in an isometric view, of a laser doping apparatus 10 in accordance with the present disclosure. The embodiment illustrated in FIG. 7A may generally have an upper enclosure 12 which may be used to house a laser optical delivery sub-system. A middle enclosure 14 may be used to house the reaction chamber and robotic arm for transferring wafers to and from auto-docking station 18. The lower enclosure 16 may be used to house the utility panel and gas system, pneumatic system, and electrical system, as well as other system components.

FIG. 7B further illustrates embodiments of laser doping apparatus 10 in accordance with the present disclosure. The particular embodiments illustrated in FIG. 7B include laser sub-system 20, optical scan head and lens 22, scan-head and lens mounting 24, optical base-plate 26, optical mounting bridge 28, and laser leveling apparatus 29. Reaction chamber 30 has a hinged lid and window assembly 32 to permit rapid access to the chamber and substrates in the chamber, and for easy access to wiping down or cleaning the chamber walls and window. The lower section 16 of laser doping apparatus 10 contains the robot controller 40, robot 42, computer sub-subsystem 44, gas box sub-system 46, and ozone generator 54. Below the main frame of laser doping apparatus 10 are casters 50 for easy transportation, and leveling feet 52 for permanent installation in a clean room fabrication facility. The components of laser doping apparatus 10 are made of clean materials compatible with a clean room environment, such as high grade stainless steel, Teflon, certain plastics, and other low-particle or particle-free materials. Load port module 60 and FOUP pod 62 are preferred embodiments of the present disclosure used to facilitate the loading and unloading of cassettes of silicon wafers from system 10.

FIG. 7C is a cutaway side view of the primary sub-systems of laser doping apparatus 10 of the present disclosure. Gas box sub-system 46 provides all the process gases to reaction chamber 30. Chamber exhaust sub-system 70 takes the by-products of the doping reaction out of the system.

FIG. 7D is a cut-away top view of the wafer loading robotic sub-system and chamber portions of a laser doping apparatus according to the present disclosure. The load port module 80 houses a cassette of silicon wafers which are transferred into the chamber 30 by end effector 82. The end effector 82 is controlled by robot 84. The end effector 82 transfers the wafer into chamber 30 where it is processed.

FIG. 7E is a cutaway view of the optical base-plate showing placement of the laser, scan head, mirrors, and optics of a laser doping apparatus of the present disclosure. The laser 20 fires a beam of pulsed radiation at one of three wavelengths according to a preferred embodiment of the present disclosure. The wavelengths are 266 nm, 355 nm, and 532 nm. The laser beam follows beam-path 21 and is collimated by collimating optics 90. The beam is then reflected by mirrors #1 and #2 in sub-system 27, an optical mirror mount. The beam then is shaped by beam-shaping optics 91. Mirror #3 25, which may be mounted between sections of beam-shaping optics 91 reflects the beam into scan-head 24.

All of the optical system, according to a preferred embodiment of the present disclosure, is placed on a vibration isolated optical base-plate 23. This permits complete modular manufacturing of the entire optical system of the laser doping apparatus of the present disclosure, thereby reducing cost. The design is simple yet effective in performing the necessary function of delivering the laser radiation to the chamber.

The beam shaping optics provide, in one embodiment, a Gaussian beam profile in the scan axis and a flat top beam in the orthogonal axis. Alternatively, the beam may be a square top-hat beam. The apparatus described herein may use refractive (lenses) and/or reflective (optical gratings) beam shaping optics. Other possibilities are to use beam homogenizers, or other convenient arrangements to convert the Gaussian shaped laser output beams into the flat beam or more uniform beam desired herein.

The beam is scanned by a galvo assembly inside the scan head, and then goes through the scan lens. The scan lens can be a large field, 5-6 element custom F-theta lens that covers a 300 mm or 450 mm field with negligible aberration, defocus, or non-orthogonal landing. The laser beam may be, in one embodiment of the present disclosure, a rectangular shaped beam. The laser may be, in another embodiment, capable of delivering separately or co-axially, three laser wavelengths, those being 266 nm, 355 nm and 532 nm. In a preferred embodiment, the laser is a YAG laser equipped with harmonic generators for all three of these wavelengths.

FIG. 7F is a cutaway top view of the placement of two different lasers on the system baseplate of a laser doping system in accordance with a preferred embodiment of the present disclosure, showing special modules or harmonic generators for various wavelengths of laser light. In one embodiment, the wavelengths are 266 nm, 355 nm, and 532 nm, and the laser is a YAG laser. In another embodiment, the laser wavelength is the natural wavelength of a YAG laser, 1064 nm.

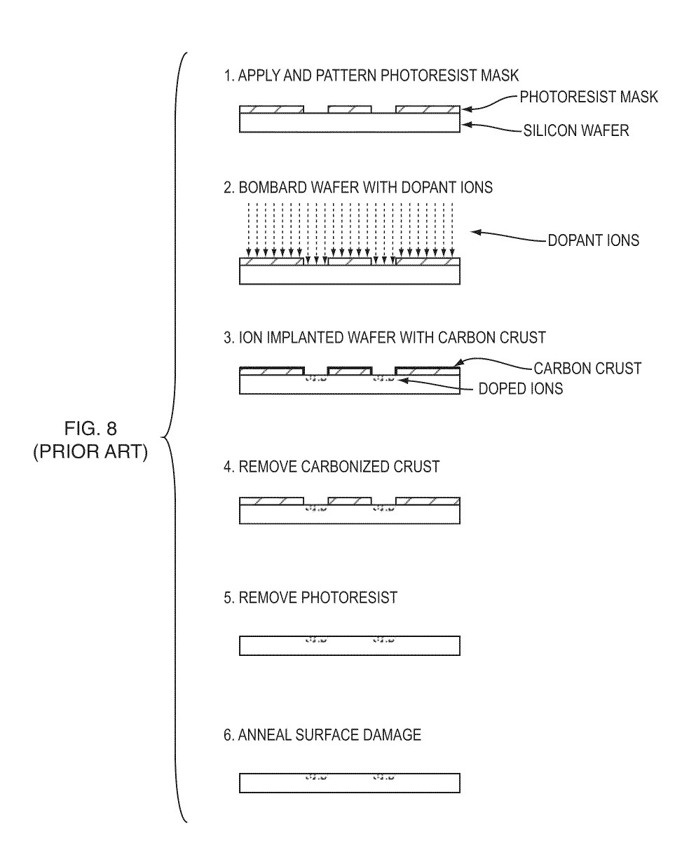

FIG. 8 is a cross-sectional process flow diagram of an ion doping method in accordance with the prior art, illustrating a semiconductor device in which impurity ions are implanted into a silicon wafer using a resist mask. In this commonly used prior art practice, there are three major problems which are solved by the present disclosure. The first problem is that the high energy ions incident on the resist mask cause the formation of a carbonized crust or thin layer of dense carbonaceous polymer that requires a complex process involving two expensive tools and several individual process steps to remove. In the present disclosure, the laser photons performing the same doping function, the surface of the resist mask does not for a carbonized crust, but just is cured slightly and is easily removed without the complexities and cost of the prior art ion implantation method.

The second problem cause by the prior art method of FIG. 8 is the damage to the surface of the wafer caused by the high energy ions. Crystal damage is so severe as to require a separate laser repair step to anneal out the damage. This adds cost, complexity and added wafer handling with attendant surface contamination that contributes to yield loss.

The third problem of the prior art method of ion implantation that is solved by the present disclosure is that it can replace complex and costly ion implanting equipment. Ion implanters are one of the largest tools in an integrated circuit factory, taking expensive clean room space. The tools themselves are highly complex systems (see example of drawing from an ion implant patent, refer to patent).

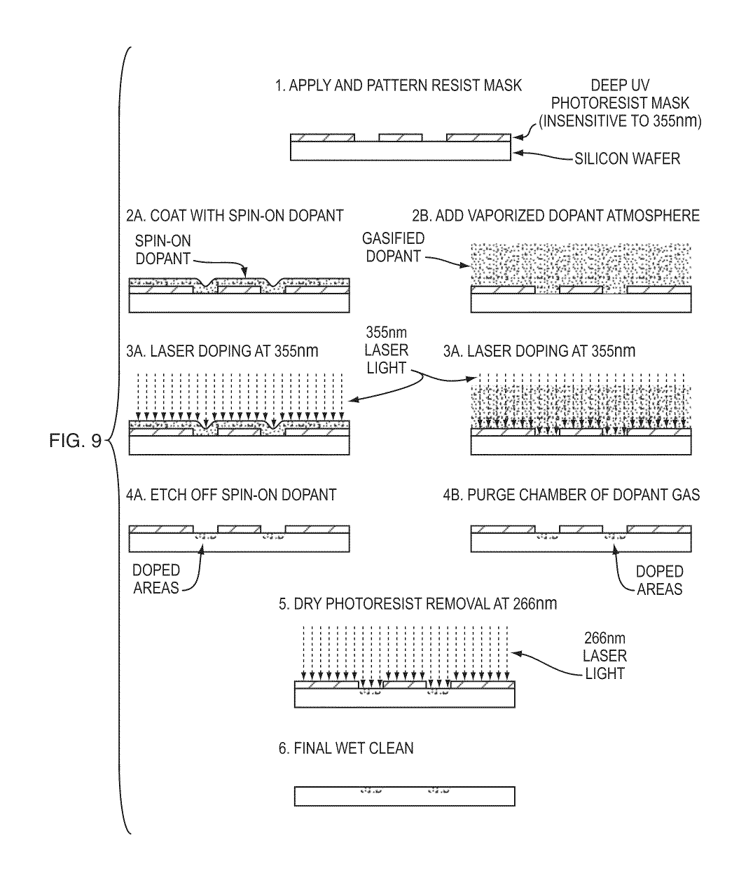

FIG. 9 is a cross sectional process flow diagram of a laser doping method in accordance with the present disclosure illustrating a semiconductor device in which impurity ions are implanted into a silicon wafer using a resist mask. The first step in laser doping is to for a resist mask. This step is used in both the present disclosure and in the prior art. In a preferred embodiment of the present disclosure, the resist used to form the doping mask is insensitive to laser light at 355 nm. The resist may be a deep UV resist that will withstand 355 nm laser radiation, but can be removed, as shown in step 5 of FIG. 9, with a 266 nm laser. The dopant species can be applied to the wafer or other substrate by either a spin on fluid (Step 2a of FIG. 9) or in a gas atmosphere (Step 2b of FIG. 9). Following doping, the spin on dopant is etched off, and in the case of a gas dopant, the chamber is simply purged of the dopant gas. The last step is removal of the doping mask. In a preferred embodiment of the present disclosure, the mask is removed with a laser beam, which may have a wavelength of 266 nm.

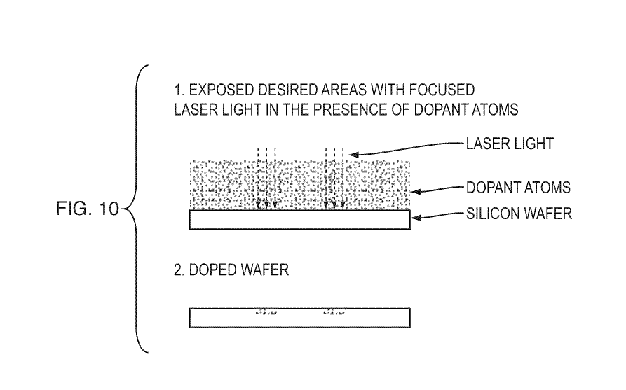

FIG. 10 is a cross sectional process flow diagram of a mask-less direct doping method in accordance with a preferred embodiment of the present disclosure. A highly focused laser beam is used to direct write the integrated circuit pattern into the silicon by directing the beam to the desired area of the implant. In an atmosphere of gaseous dopant atoms, the dopant is driven in only in those areas irradiated by the laser photons. This direct laser doping method eliminates the need for a resist mask and all the added steps associated with resist masking and mask removal after doping. The exposure source shown in FIG. 7b is capable of writing sub-micron images by using a highly focused laser beam, and a computer program with the pattern information to direct the beam to the desired places on the wafer or other substrate. The direct laser doping method, as a preferred embodiment of the present disclosure, will permit significant cost reduction compared to present methods using complex ion implanters and resist masks.

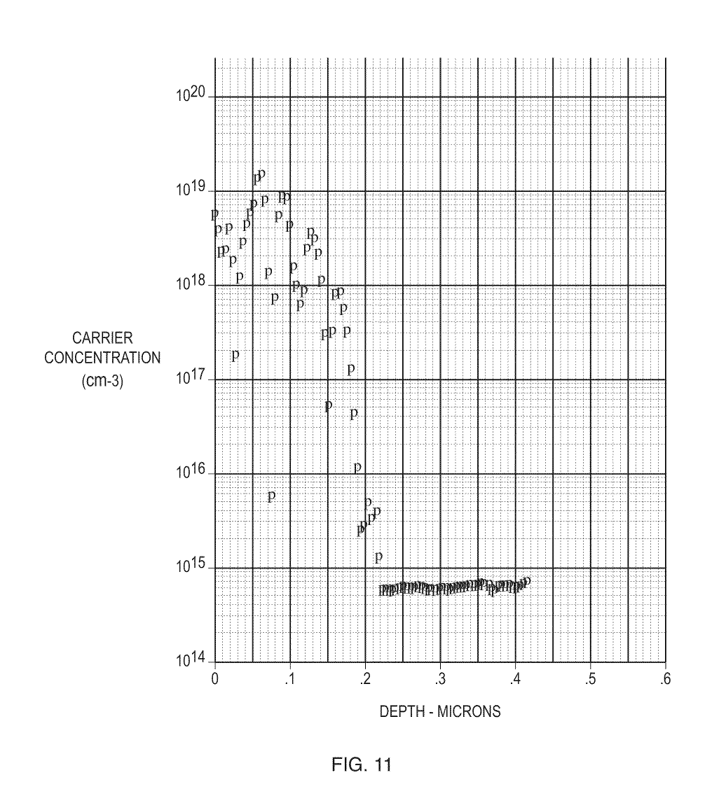

FIG. 11 is a graph of electrical data of laser doping of boron on a boron-doped substrate in accordance with the present disclosure. Each plotted letter ‘P’ represents the concentration of boron at a particular depth below the surface of the silicon substrate. At depths greater than 0.22 um (right side of the graph), we see the background boron concentration (˜6×10¹⁴ cm⁻³) in the silicon wafer before processing. At depths shallower than 0.22 um (left side of the graph) we see the total of this original boron concentration plus the much greater concentration (several thousand times as much) of additional boron driven into the silicon surface layers by the laser doping process.

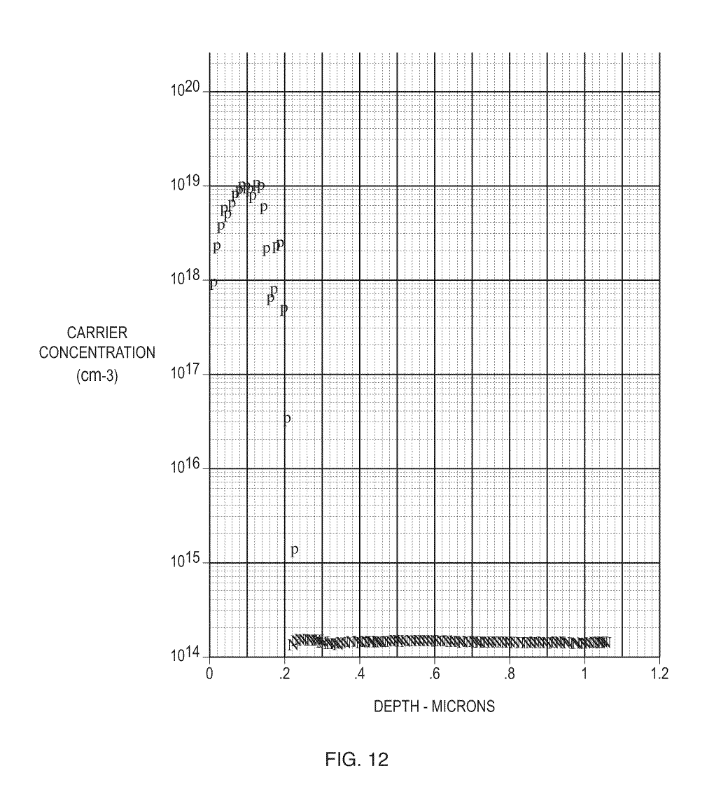

FIG. 12 is a graph of electrical data of laser doping of a junction of boron on a phosphorus-doped film formed in accordance with the present disclosure. Each plotted letter ‘P’ represents the concentration of boron at a particular depth below the surface of the silicon substrate, and each plotted letter ‘N’ represents the concentration of phosphorus at a particular depth below the surface. At depths greater than 0.22 um (right side of the graph) we see the background phosphorus concentration (˜1.5×10¹⁴ cm⁻³) in the silicon wafer before processing. At depths around 0.22 um and below (left side of the graph) we see that the majority dopant has become P-type, producing a p-on-n diode junction. This is the result of a much higher concentration of boron (several tens of thousand times as much as the starting phosphorus concentration) which was driven into the silicon surface layers by the laser doping process.

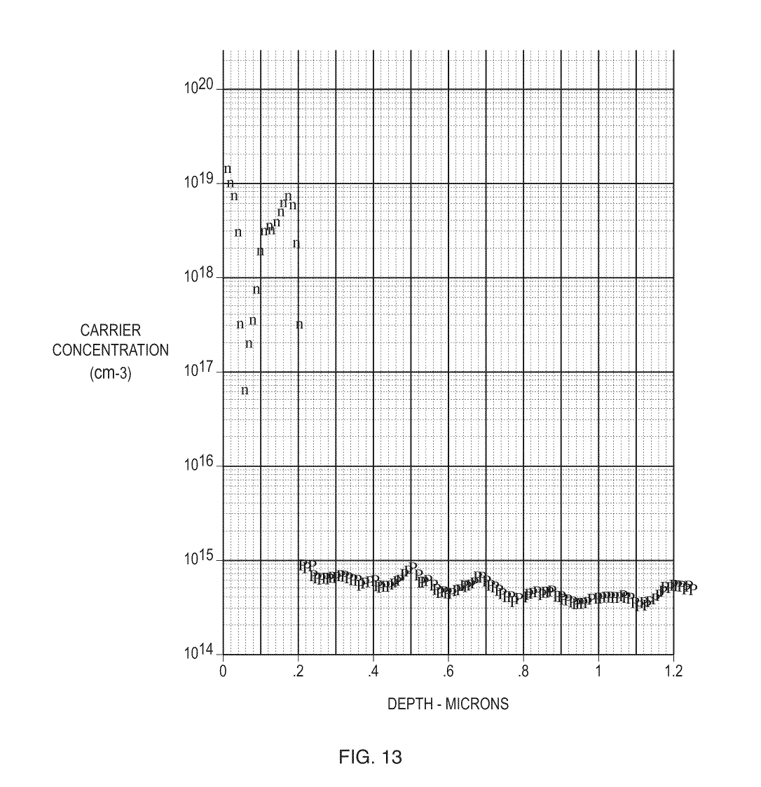

FIG. 13 is a graph of electrical data of laser doping of a junction of phosphorus on a boron-doped substrate formed in accordance with the present disclosure. Each plotted letter ‘P’ represents the concentration of boron at a particular depth below the surface of the silicon substrate, and each plotted letter ‘N’ represents the concentration of phosphorus at a particular depth below the surface. At depths of 0.22 um or greater (right side of the graph) we see the background boron concentration (˜6×10¹⁴ cm⁻³) in the silicon wafer before processing. At depths shallower than 0.22 um (left side of the graph) we see that the majority dopant has become N-type, producing an n-on-p diode junction. This is the result of a much higher concentration of phosphorus (several thousand times as much as the starting boron concentration) which was driven into the silicon surface layers by the laser doping process.

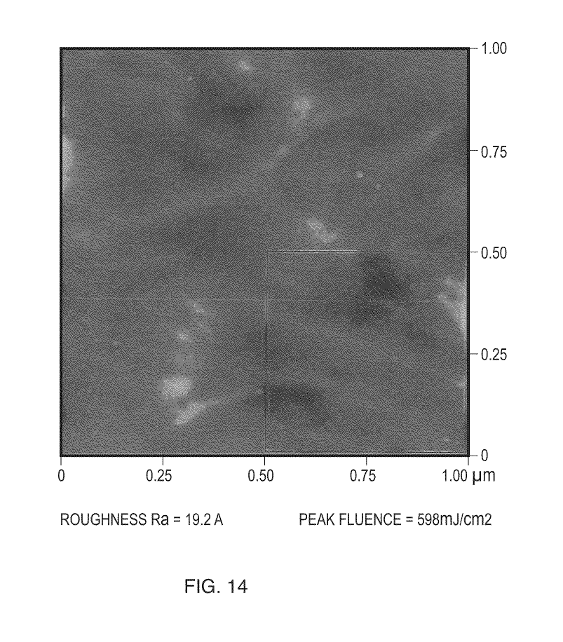

FIG. 14 is an atomic force micrograph of the surface of a wafer following laser doping in accordance with the present disclosure. In a preferred embodiment of the present disclosure, the laser beam is homogenized to create a highly uniform top-hat-shaped beam that will permit laser doping without any significant roughening of the wafer surface. In another related embodiment, the energy density of the laser beam (fluence) will be sufficiently high to permit direct laser doping or doping with a resist mask, and that fluence level is below the energy density that causes roughening of the wafer surface.

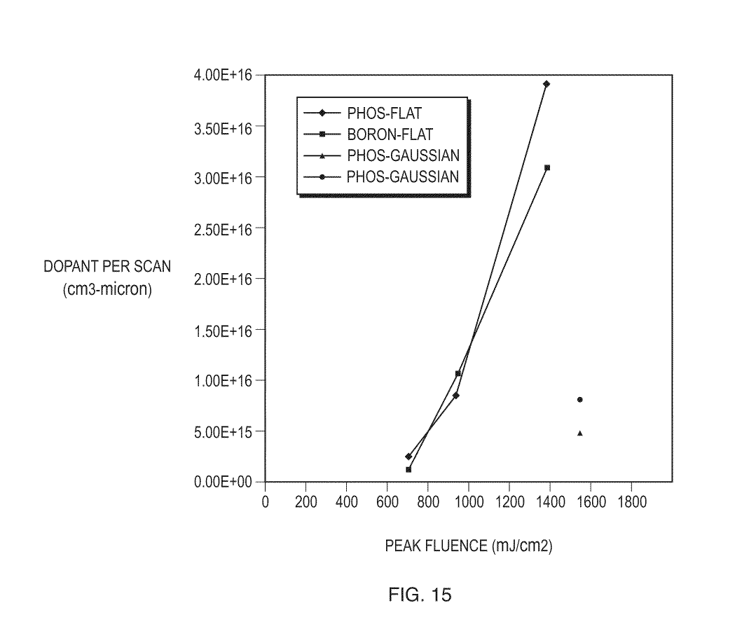

FIG. 15 is a graph of dopant concentration as a function of laser energy per unit area (fluence) in accordance with the present disclosure. This figure illustrates the advantage of the flat-shaped laser beam of the present disclosure compared to the Gaussian beam of the prior art. Note that a significant amount of laser doping can be achieved at relatively low fluence with the flat beam of the present disclosure, while the prior art Gaussian beam requires much higher fluence for an equivalent amount of doping.

### Example

Referring to FIG. 7, a method of doping a silicon (or other semiconductor) substrate in a first example according to the present disclosure will be described. The semiconductor surface would contain a pattern of electronic devices, with exposed areas requiring addition and activation of dopant species.

A liquid containing a dissolved dopant such as boron or phosphorus is applied to a silicon wafer (spinning at ˜2500 rpm), to form a thin layer (˜0.4 to ˜1.2 um thick) which solidifies as the solvent evaporates at room temperature. The wafer is next baked at ˜100° C. for ˜1 minute to continue removing solvents from the dopant-containing coating. Finally, the wafer is baked at ˜200° C. for ˜10 minutes to drive off the volatile organics from the coating, and cure the remaining dopant film matrix to make it suitable for controllable laser processing.

The wafer thus coated is then loaded onto a heatable chuck (20-90° C.) in a reaction chamber with a gas containing oxygen flowing at 2-6 slm, preferably at less than atmospheric pressure, and exposed to a scanning pulsed laser beam. As the laser beam heats the substrate and coating, the film's organic matrix is volatilized and its dopant material is driven into the underlying silicon crystal.

An alternate embodiment would be to laser-process an uncoated silicon or other semiconductor wafer in an atmosphere with a gas containing dopants such as boron, phosphorus or arsenic.

The pulsed laser beam preferred embodiment is square in shape with a flat intensity profile, but a round beam with Gaussian profile has also been used successfully. The laser wavelength preferred embodiment is 355 nm, but other wavelengths (ultraviolet, visible and near-infrared) may also be used.

The laser beam is q-switched and scanned at rates which will cover the wafer surface with a tiled array of pulses. The overlap of these pulses is set to make the overall surface dose as uniform as possible. After each scan, the pattern of landed pulses is offset, so that as the number of scans is increased, the integrated dose uniformity continues to improve.

After completion of the laser scanning, the remaining dopant film is etched off in a buffered HF solution. Then, electrical measurements are made on the surface (sheet resistance via 4-point probe) and on beveled cross-sections (spreading resistance).

What follows is a summary of our experiments (on unpatterned wafers) showing changes in silicon conductivity and dopant distribution resulting from exposing spun-on-dopant films to various laser pulse peak fluences and doses. In each of the experiments, laser-scanning over a band of the surface caused a shift in the sheet resistance (Rs) by moving dopant from the surface film into the underlying crystalline silicon substrate.

The teachings of all patents, published applications and references cited herein are incorporated by reference in their entirety.]

While this invention has been particularly shown and described with references to example embodiments thereof, it will be understood by those skilled in the art that various changes in form and details may be made therein without departing from the scope of the invention encompassed by the appended claims.

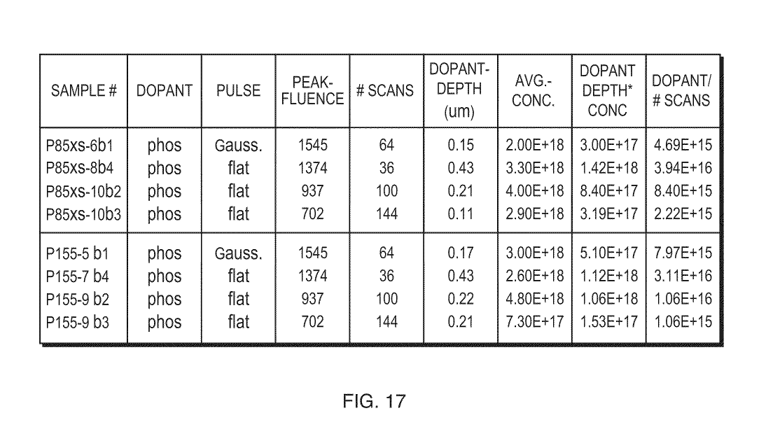

In the eight cases listed in the table of FIG. 17, the laser-scanned band was cleaved and spreading resistance measurements were made to determine the depth, concentration and type of the dopant which had been driven in by the laser. Successful results can be seen for boron and phosphorus, using both flat and Gaussian pulse shapes.

While the disclosure has been described in terms of a number of specific embodiments, it will now be evident that many alternative variations, configurations, modifications are within the scope of the teachings contained herein. For example, variations in the optical system used to shape the laser beam may be used to accommodate the direct imaging requirements of various device geometries.

Accordingly, the present invention should not be limited by the embodiments used to exemplify it but rather should be considered to be within the spirit and scope of the following claims, and equivalents thereto, including all such alternatives, modifications and variations.

For example, in a first aspect, the invention may be claimed as an apparatus for doping a surface with a dopant consisting of directing a beam of laser radiation into a chamber containing a dopant and a substrate, wherein the laser beam and reactant interact at the surface of the substrate to cause the reactant to enter the surface of the substrate.

The dopant may be present at the surface of the substrate in the form of a vapor, a liquid layer or a solid film.

In another aspect, the invention may be claimed as an apparatus for doping of a semiconductor material with a dopant consisting of an optical system configured to direct 266 nm, 355 nm, and 532 nm laser radiation, one wavelength at a time, into a gas reaction chamber where the laser beam interacts with dopants at the surface of the substrate to cause the reactant to enter the surface of the substrate.

For a still further aspect, the invention may be claimed as an apparatus for doping of a semiconductor material using an optical system capable of delivering square-shaped laser pulses into a gas reaction chamber where the laser beam interacts with dopants at the surface of the substrate to cause the reactant to enter the surface of the substrate.

In a still further aspect, the invention can be an apparatus for direct laser doping of a semiconductor material using a optical system capable of sub-micron resolution necessary to directly form conductive paths without the use of a photoresist mask.

Other claims may incorporate the following concepts or methods:
1. Tiling of pulses for dose uniformity, abutting of pulses having square or hexagonal shapes, with various scanning methods, and optionally, programmable. The origin of sequential scans may be shifted, to improve averaging of dose uniformity.
2. Controlled energy sequence to produce graded doping profile (deep at center, shallow at edges). In one example, could do three passes at different energy levels at offset location.
3. Deep UV resist chosen for effective masking with 355 nm doping, and then (at least partly) removed with 266 nm cleaning Thus the same apparatus could be used for two sequential process steps in fabrication.
4. No vibration issues because no need for x-y stage motion.

Compared with deep UV lasers (high eV/photon, more risk of substrate damage and roughening), crustless doping may be possible at 355 nm with combination of low temperature, low fluence and more scans or variable scan algorithms to avoid hot spots.

What is claimed is:

1. An apparatus comprising:
a reaction chamber;
a semiconductor substrate support, located within the reaction chamber, for supporting a semiconductor substrate;
a laser source for providing a laser beam;
a beam shaper, arranged to receive the laser beam and for providing a shaped laser beam at an output such that the shaped laser beam has a uniform energy distribution in a selected direction orthogonal to the semiconductor substrate support; and
an optical scan head, arranged with respect to the laser source, beam shaper, and/or the semiconductor substrate, to position the shaped laser beam in two dimensions along a surface of the semiconductor substrate.

2. The apparatus of claim 1 wherein a cross sectional area of the shaped laser beam is much smaller than a cross sectional surface area of the semiconductor substrate.

3. The apparatus of claim 1 wherein the shaped laser beam has a rectangular cross sectional shape.

4. The apparatus of claim 1 additionally comprising:
a scan head position controller, for controlling a position of the scan head such that successive activations of the laser source are in non-adjacent areas of the substrate.

5. The apparatus of claim 1 wherein the shaped laser beam has a Gaussian shape in an axis parallel to the semiconductor substrate.

6. An apparatus comprising:
a reaction chamber;
a gas source, for providing a flowing gas to the reaction chamber;
a semiconductor substrate support, located within the reaction chamber, for supporting a semiconductor substrate;
a laser source for providing one or more laser beams at wavelengths selected from at least 266 nm, 355 nm and 532 nm;
a beam shaper, arranged to receive the one or more laser beams and for providing one or more shaped laser beams into the reaction chamber such that the shaped laser beams have a uniform energy distribution in a selected direction orthogonal to the semiconductor substrate support; and
an optical scan head, arranged with respect to the laser source, beam shaper, and/or the semiconductor substrate, to position the shaped laser beams in two dimensions along a surface of the semiconductor substrate.

7. The apparatus of claim 6 wherein two or more of the laser beams are individually aligned.

8. The apparatus of claim 6 wherein two or more of the laser beams are co-axially aligned.
